(19) United States
(12) Patent Application Publication
(10) Pub. No.: US 2007/0218574 A1
(43) Pub. Date: Sep. 20, 2007

(54) Semiconductor laser manufacturing method

(75) Inventors: Satoshi Kajiyama, Yamanashi (JP); Hiroyuki Sumitomo, Yamanashi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES INC., Yamanashi (JP)

(21) Appl. No.: 11/717,676

(22) Filed: Mar. 14, 2007

(30) Foreign Application Priority Data
Mar. 15, 2006 (JP) 2006-071737

(51) Int. Cl. H01L 21/479; H01L 21/66

(52) U.S. Cl. 438/22; 438/45; 438/466; 438/17

(57) ABSTRACT

A method of manufacturing a semiconductor laser that has a ridge portion formed with a compound semiconductor layer containing Ga includes applying an electric current to the semiconductor laser until the characteristics of the semiconductor laser that have deteriorated due to the application of the electric current recover from the deterioration.

### BACKGROUND OF THE INVENTION

1. Field of the Invention

The present invention generally relates to a semiconductor laser manufacturing method, and more particularly, to a semiconductor laser manufacturing method that includes the step of applying an electric current.

2. Description of the Related Art

In recent years, semiconductor lasers are used in the field of optical communication and optical storage media devices. Particularly, for optical storage media devices (optical disc devices such as CDs and DVDs), semiconductor lasers having short wavelengths such as optical wavelengths are required, as the storage density has become higher. In a semiconductor laser with short wavelengths, a compound semiconductor containing Ga such as AlInGaP is provided. For example, Japanese Unexamined Patent Publication No. 2005-317572 discloses a semiconductor laser (prior art 1) that has a ridge structure (or a ridge portion) having side faces made of AlGaInP. In this semiconductor laser, an active layer that emits laser light is interposed between an n-type clad layer and a p-type clad layer. A current (an electric current) is applied to the portion between the n-type clad layer and the p-type clad layer, so that the laser light is emitted. Some semiconductor lasers deteriorate only after short-time use (early degradation). Therefore, an electric current is applied to each semiconductor laser at a high temperature after the production of the semiconductor lasers. In accordance with this method, semiconductor lasers that deteriorate due to the application of the electric current are determined to be defective products. Japanese Unexamined Patent Publication No. 2001-176661 discloses a method of recovering luminance by causing electric field aging or heat aging in an organic EL device.

However, the production costs become high where the number of semiconductor lasers that deteriorate due to the application of an electric current is large.

### SUMMARY OF THE INVENTION

The present invention has been made in view of the above circumstances and provides a semiconductor laser manufacturing method that can reduce the number of semiconductor lasers that deteriorate due to the application of an electric current and lower the production costs.

According to one aspect of the present invention, there is provided a method of manufacturing a semiconductor laser that has a ridge portion formed with a compound semiconductor layer containing Ga, the method including: applying an electric current to the semiconductor laser until characteristics of the semiconductor laser that deteriorate due to the application of the electric current recover from the deterioration. The number of semiconductor lasers that deteriorate due to the application of an electric current can be reduced, and the production costs can be lowered.

According to another aspect of the present invention, there is provided a method of manufacturing a semiconductor laser that has a ridge portion formed with a compound semiconductor layer containing Ga, the method including: applying an electric current to the semiconductor laser; distinguishing the semiconductor laser that does not satisfy predetermined selecting requirements from other semiconductor lasers after the step of applying an electric current; and applying an electric current again to the semiconductor laser that does not satisfy the predetermined selecting requirements, energization through the step of applying an electric current and the step of applying an electric current again being performed to recover characteristics of the semiconductor laser from deterioration. The second energizing step is not performed for semiconductor lasers that have not deteriorated in the first energizing step. Accordingly, the production costs can be lowered.

### BRIEF DESCRIPTION OF THE DRAWINGS

Exemplary embodiments of the present invention will be described in detail with reference to the following drawings, wherein:

FIG. 1 is a perspective view of a semiconductor laser in accordance with the present invention;

FIG. 2A and FIG. 2B are cross-sectional views of the semiconductor laser;

FIG. 3 illustrates the principles of the present invention;

FIG. 4A and FIG. 4B show the optical outputs and the electric currents before and after energization;

FIG. 5 illustrates an assumed mechanism of the deterioration of semiconductor laser C;

FIG. 6 is a flowchart showing a method of manufacturing semiconductor lasers in accordance with the first embodiment;

FIG. 7A through FIG. 7D are cross-sectional views showing the procedures for manufacturing semiconductor lasers in accordance with the first embodiment; and

FIG. 8 is a flowchart showing a method of manufacturing semiconductor lasers in accordance with a second embodiment of the present invention.

### DESCRIPTION OF THE PREFERRED EMBODIMENTS

A description will now be given, with reference to the accompanying drawings, of exemplary embodiments of the present invention.

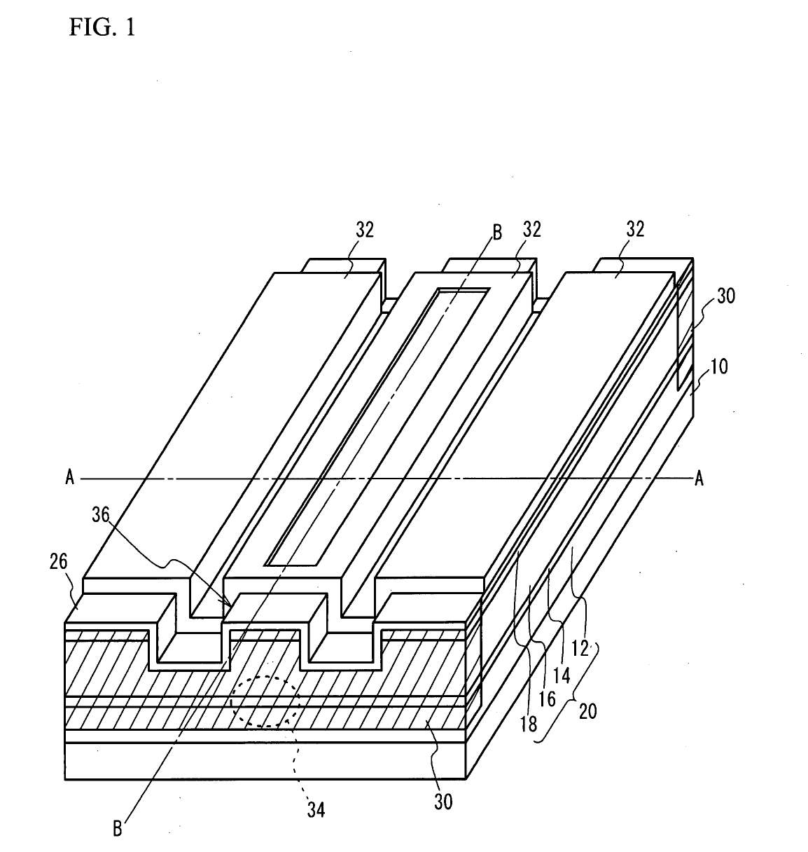

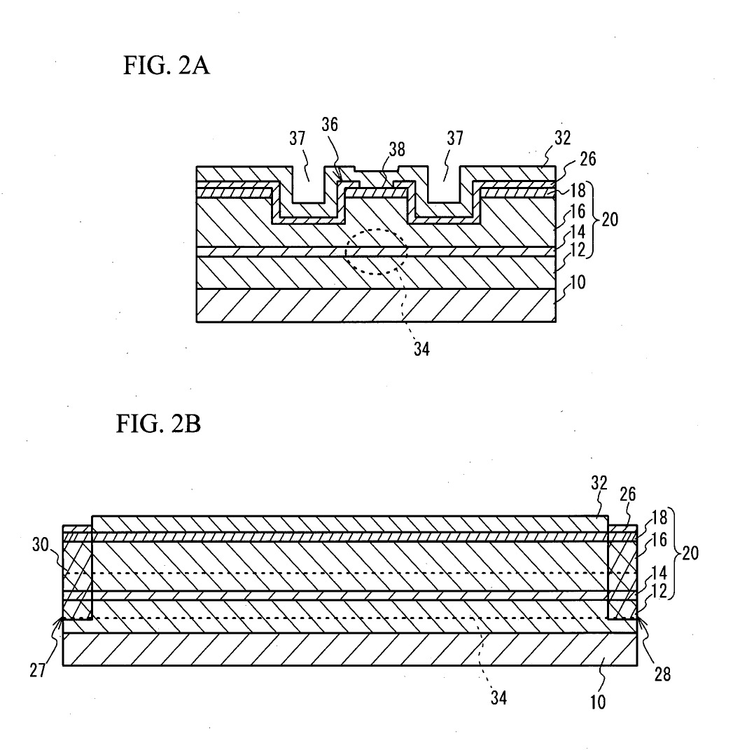

First, a semiconductor laser having a ridge portion is described. FIG. 1 is a perspective view of a semiconductor laser in accordance with a first embodiment of the present invention. FIG. 2A is a cross-sectional view of the semiconductor laser, taken along the line A-A of FIG. 1. FIG. 2B is a cross-sectional view of the semiconductor laser, taken along the line B-B of FIG. 1. As shown in FIGS. 1, 2A, and 2B, a compound semiconductor layer 20 that includes an n-type clad layer 12, an active layer 14, a p-type clad layer 16, and a p-type contact layer 18 is provided on an n-type GaAs substrate 10.

As shown in FIG. 2A, concave portions 37 are formed by removing some parts of the p-type GaAs contact layer 18 and the p-type AlGaInP clad layer 16. A ridge portion 36 that is formed with a part of the p-type clad layer 16 and the p-type contact layer 18 is formed between the concave portions 37. A silicon nitride film 26 is formed on the p-type clad layer 16 and in contact with the side faces and the upper face of the ridge portion 36. An opening 38 is formed at a portion of the silicon nitride film 26 located above the p-type contact layer 18. An electrode 32 is provided on the silicon nitride film 26 and in the opening 38. The electrode 32 is in ohmic contact with the p-type contact layer 18 via the opening 38. As shown in FIG. 2A and FIG. 2B, diffusion regions 30 are provided at end portions of the compound semiconductor layer 20 in the B-B direction.

Since the active layer 14 is interposed between the n-type AlGaInP clad layer 12 and the p-type clad layer 16 each having a low refractive index, as shown in FIG. 2A, the light traveling through the compound semiconductor layer 20 is caught at a portion in the vicinity of the active layer 14. The equivalent refractive index with respect to the light traveling through a portion that is located near the active layer 14 and below the ridge portion 36 is higher than the equivalent refractive index with respect to the light traveling through portions that are located near the active layer 14 and below the concave portions 37 on both sides of the ridge portion 36. Accordingly, the light traveling near the active layer 14 is caught in the portion that is located near the active layer 14 and below the ridge portion 36. The portion that catches the light traveling near the active layer 14 is referred to as a waveguide 34. The ridge portion 36 is a convex portion that is a part of the compound semiconductor layer 20 and is designed for the formation of the waveguide 34. As a current (electric current) flows between the electrode 32 and the substrate 10, the light generated from the active layer 14 is caught in the waveguide 34, as described above. As shown in FIG. 2B, the light in the waveguide 34 is reflected by the end faces 27 and 28 on both sides of the compound semiconductor layer 20. In this manner, the light guided and released as laser light in the waveguide 34 is emitted as output light from the end face 27.

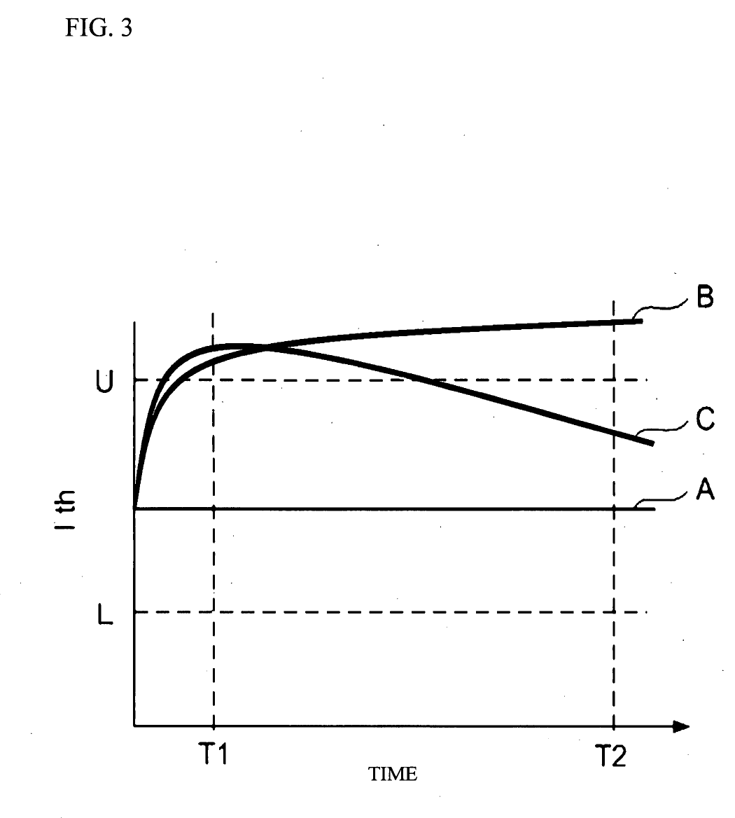

FIG. 3 is a schematic diagram showing the lasing threshold current Ith of the semiconductor laser with respect to time observed where an electric current is applied to the semiconductor laser at a high temperature. Ideally, the threshold current Ith does not change even when an electric current is applied, like the threshold current of a semiconductor laser A. If the threshold current Ith is within a predetermined range (in the range of U to L in FIG. 3, for example) or the change in threshold current Ith is within a predetermined range after an electric current is applied to a semiconductor laser for a predetermined period of time, the semiconductor laser is regarded as acceptable. In the case of a semiconductor laser B shown in FIG. 3, the threshold current Ith exceeds the upper limit value U of the threshold current Ith after a predetermined period of time has passed, and the semiconductor laser B is regarded as a defective product. The threshold current Ith is measured before and after application of an electric current of 120 mA at a temperature of 80° C. for one to three hours, for example. In this manner, acceptable semiconductor lasers are distinguished from defective semiconductor lasers.

The inventor found that there was a semiconductor laser like a semiconductor laser C in which the threshold current Ith is changed greatly by application of an electric current but is recovered by continuing the energization thereafter. In FIG. 3, the semiconductor laser C has the threshold current Ith exceeding the upper limit value U after energization is performed over the period of time T1. As a result, the semiconductor laser C becomes a defective product. However, as the energization is continued, the threshold current Ith returns to a small value, and becomes lower than the upper limit value U after the energization is performed over the period of time T2. In this manner, the inventor discovered the phenomenon where a semiconductor laser that deteriorated once due to the application of an electric current recovered by virtue of the continued application of an electric current.

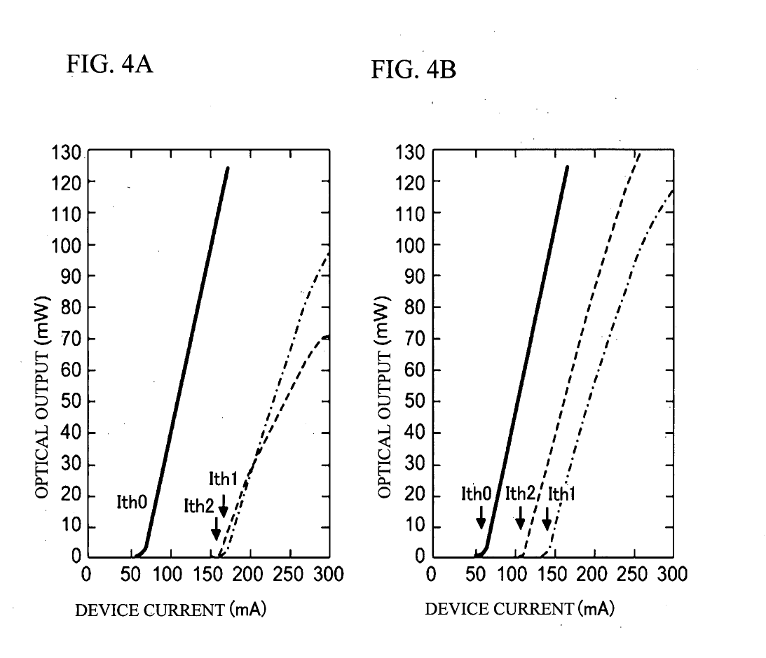

FIG. 4A and FIG. 4B show the optical outputs (optical output characteristics) of semiconductor lasers with respect to electric currents that are observed before and after the application of the electric currents to the semiconductor lasers. In each of the graphs, the solid line indicates the optical output characteristics that are observed before energization, the dot-and-dash line indicates the optical output characteristics that are observed after an electric current of 120 mA is applied at an operating temperature of 70° C. for 10 hours (energization 1), and the dashed line indicates the optical output characteristics that are observed after an electric current of 120 mA is applied at an operating temperature of 80° C. for 50 hours (energization 2). The value of an electric current at which an optical output first appears while the electric current is being increased is the lasing threshold current Ith. The ridge portion 36 of each semiconductor laser used here is 2.8 mm in length and 2 μm in width. As shown in FIG. 4A, in the semiconductor laser B, a threshold current Ith1 that is observed after the energization 1 is higher than a threshold current Ith0 that is observed before the application of an electric current. A threshold current Ith2 that is observed after the energization 2 is almost the same as the threshold current Ith1. In this manner, the threshold current of the semiconductor laser B does not recover from deterioration even after the energization is continued. In the semiconductor laser C, on the other hand, the threshold current Ith1 that is observed after the energization 1 is higher than the threshold current Ith0 before the application of an electric current, and the threshold current Ith2 that is observed after the energization 2 becomes lower, as shown in FIG. 4B. Accordingly, the semiconductor laser C recovers from deterioration. Although the temperature at which the energization 1 is performed is 70° C., the same results can be obtained at a temperature of 80° C. Also, the threshold currents Ith have been described as the characteristics of the semiconductor lasers that deteriorate due to energization, other characteristics such as optical outputs also deteriorate due to energization. Accordingly, the same phenomenon can also be described through those other characteristics.

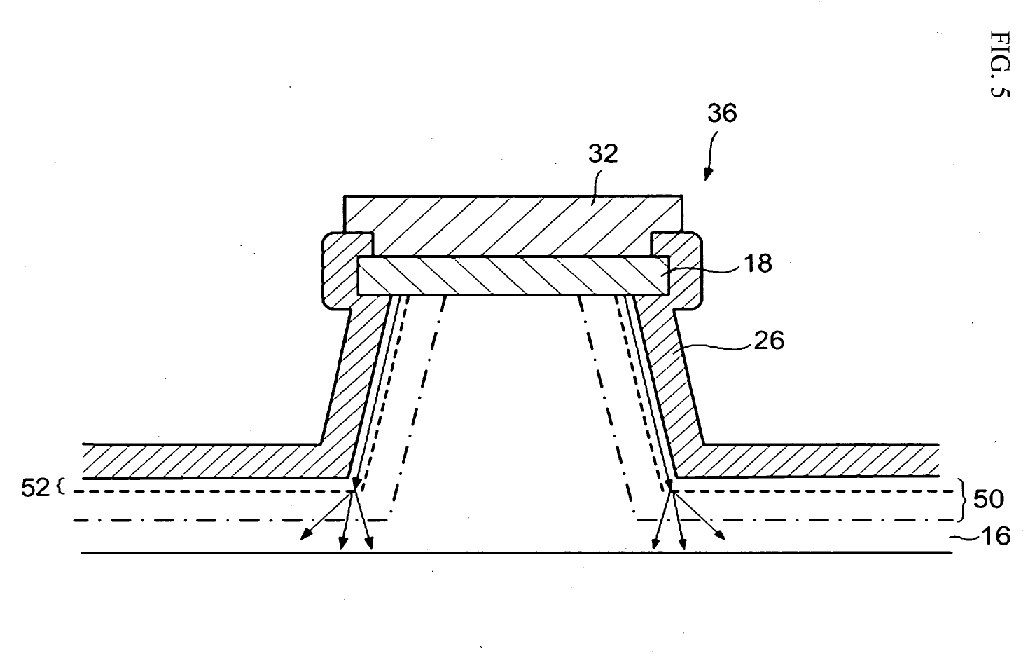

Although the mechanism of this phenomenon is not clear, the following is conceivable. FIG. 5 is a cross-sectional view of the ridge portion 36 and the portion surrounding the ridge portion 36 of the semiconductor laser shown in FIG. 2A. The same components as those shown in FIG. 2A are denoted by the same reference numerals as those in FIG. 2A, and explanation of them is omitted herein. As shown in FIG. 5, a depletion layer 50 is formed at the interface between the p-type AlGaInP clad layer 16 and the silicon nitride film 26. Accordingly, a current does not easily flow through the interface between the p-type clad layer 16 and the silicon nitride film 26. However, the Ga of the p-type AlGaInP clad layer 16 easily diffuses into the silicon nitride film 26. As a result, a Ga defect is caused at the interface between the AlGaInP clad layer 16 and the silicon nitride film 26, and a defect layer 52 that is rich in V-group elements is formed. When an electric current is applied to such a semiconductor laser, the current flows in the directions indicated by arrows in FIG. 5, due to the defect layer 52. As the current flows into the defect layer 52, the current spreads under the side faces of the ridge portion 36, and flows into the p-type clad layer 16. As a result, the area in which the current flows appears to increase, and the threshold current Ith supposedly becomes higher. When an electric current is applied to the semiconductor laser, the amount of current flowing through the defect layer 52 increases, and the threshold current becomes higher. However, after the application of an electric current via the defect layer 52 is continued, the defect of the defect layer 52 is reduced, and the amount of current flowing through the defect layer 52 decreases. The threshold current recovers from deterioration supposedly in this manner.

The reason that the Ga of the p-type AlGaInP clad layer 16 easily diffuses into the silicon nitride film 26 may be that the Si of the silicon nitride film 26 attracts the Ga. Therefore, the same phenomenon may be observed where a silicon oxide film or a silicon oxynitride film is employed in place of the silicon nitride film 26. Also, the same phenomenon as above may be caused where the compound semiconductor layer forming the ridge portion 36 may be any compound semiconductor layer containing Ga other than an AlGaInP layer.

### First Embodiment

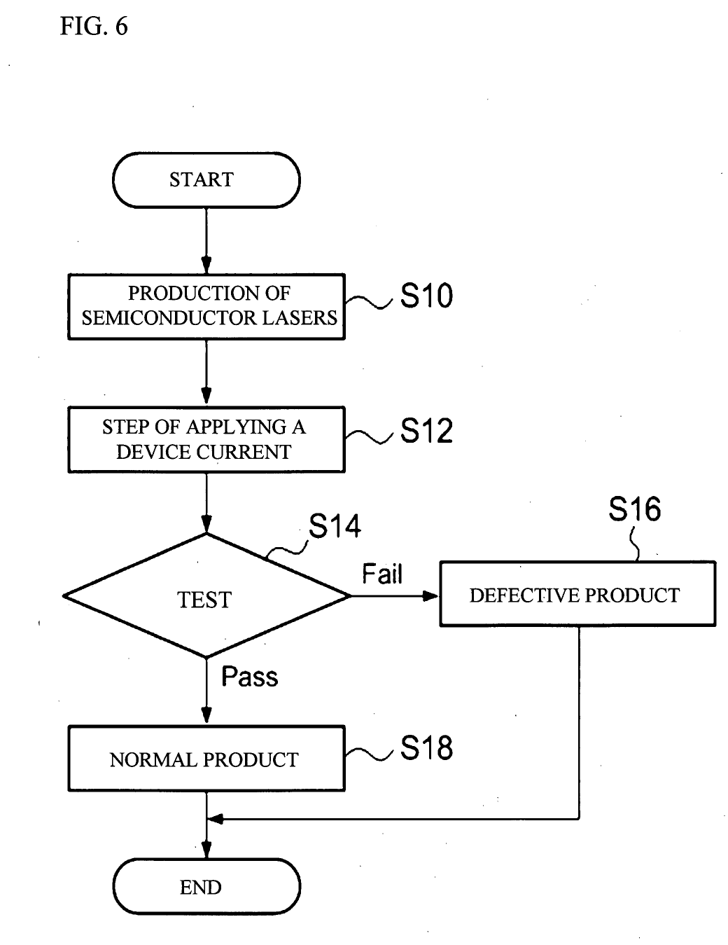

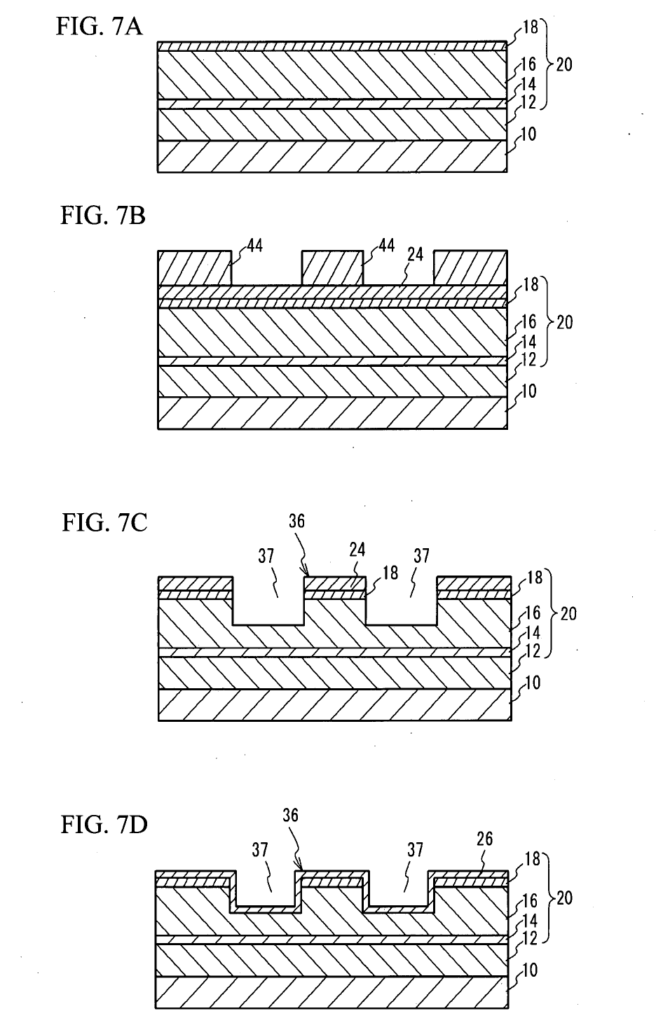

FIG. 6 is a flowchart showing a method of manufacturing semiconductor lasers in accordance with the first embodiment of the present invention. First, semiconductor lasers are produced (step S10). FIG. 7A and FIG. 7B are cross-sectional views illustrating the method of manufacturing the semiconductor lasers, taken along the line A-A of FIG. 1.

As shown in FIG. 7A, the compound semiconductor layer 20 including the n-type clad layer 12 formed with an AlGaInP layer, the active layer 14 formed with a MQW (multi quantum well) made of InGaP/AlGaInP, the p-type clad layer 16 formed with an AlGaInP layer, and the p-type contact layer 18 formed with a GaAs layer and doped with Zn is formed on the n-type GaAs substrate 10 by MOCVD. The diffusion regions 30 having Zn or the like diffused in the compound semiconductor layer 20 are then formed (see FIG. 2B).

As shown in FIG. 7B, a silicon nitride film 24 is formed in contact with the p-type contact layer 18. A photoresist 44 for forming the concave portions 37 is formed on the silicon nitride film 24.

As shown in FIG. 7C, with the photoresist 44 serving as a mask, the silicon nitride film 24 is removed. With the remaining silicon nitride film 24 serving as a mask, parts of the p-type contact layer 18 and the p-type clad layer 16 are removed. In this manner, the concave portions 37 having the bottom portions located in the p-type clad layer 16, and each ridge portion 36 interposed between two concave portions 37 are formed.

As shown in FIG. 7D, the remaining silicon nitride film 24 is removed. The silicon nitride film 26 is then formed in contact with the surface of the p-type clad layer 16, the side faces of each ridge portion 36, and the surface of the p-type contact layer 18 by plasma CVD, for example. An opening is formed in the portion of the silicon nitride film 26 located on each ridge portion 36, and each electrode 32 (the contact electrode) is formed with Ti, Mo, Au in this order by a vapor deposition technique or a sputtering technique. The structure is divided into chips, and the end faces 27 and 28 (see FIG. 2B) are coated. In this manner, semiconductor lasers are produced.

Referring back to FIG. 6, each of the semiconductor lasers is maintained at a high temperature and is energized (the step of applying an electric current: step S12). The energization is performed until the threshold current Ith (the characteristics) of each semiconductor laser recovers from deterioration caused by the application of the electric current, as is observed in the semiconductor laser C of FIG. 3. In other words, the energization is performed under such conditions that each semiconductor laser recovers from the deterioration caused by the application of the electric current. Since the energizing period of time required for each semiconductor laser to recover from the deterioration is 60 hours, the energization is performed at an operating temperature of 80° C. for 60 hours, with an electric current of 120 mA being applied to each semiconductor laser, for example. To distinguish semiconductor lasers that deteriorate due to the energization (step S12) from the other semiconductor lasers, an electric and optical test is carried out to test the threshold current Ith or the like of each semiconductor laser (step S14). If the result falls within a predetermined range, the semiconductor laser is determined to be a normal product (step S18). If the result is outside the predetermined range, the semiconductor laser has failed the test and is determined to be a defective product (step S16).

Where the energization is performed over a period of time equivalent to the energizing time T1 shown in FIG. 3, the semiconductor lasers B and C are regarded as defective products. In the first embodiment, on the other hand, the energization is performed under such conditions that each semiconductor laser recovers from deterioration caused by the application of the electric current. More specifically, the energization is performed over a period of time equivalent to the energizing time T2 shown in FIG. 3. As a result of this, the semiconductor laser B remains as a defective product, but the semiconductor laser C becomes a normal product. In this manner, the number of semiconductor lasers that deteriorate due to the application of an electric current can be reduced, and the production costs can be lowered.

### Second Embodiment

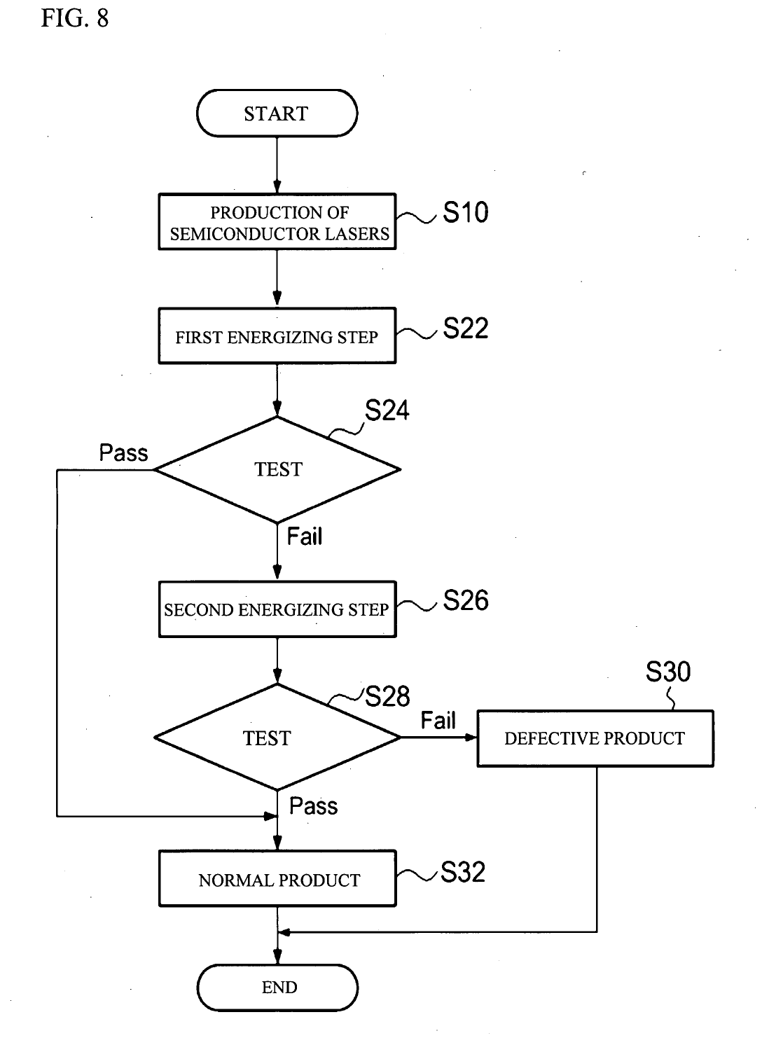

A second embodiment of the present invention concerns an example case where the energizing step is carried out twice. FIG. 8 is a flowchart showing a method of manufacturing semiconductor lasers in accordance with the second embodiment. As shown in FIG. 8, semiconductor lasers are first produced, as in step S10 of the first embodiment. Each of the semiconductor lasers is maintained at a high temperature and is energized (the first energizing step of applying an electric current: step S22). The energization is performed under such conditions that the threshold current Ith of each of the semiconductor lasers B and C exceeds the upper limit value U, as in the case with the energizing time T1 of FIG. 3. After approximately 10-hour energization, each semiconductor laser can be determined whether to be normal or not, as shown in FIG. 3. Accordingly, the energization is performed at an operating temperature of 70° C. for 10 hours, with an electric current of 120 mA being applied to each semiconductor laser. To distinguish the semiconductor lasers that have deteriorated in the first energizing step (step S22) from the other semiconductor lasers, the same test as in step S14 of the first embodiment is conducted (step S24). The semiconductor lasers that have passed the test move on to step S32 and are determined to be normal products. The semiconductor lasers that have failed the test (do not satisfy predetermined selecting requirements) move on to step S26. In this manner, the semiconductor devices that do not satisfy the predetermined selecting requirements are distinguished from the other semiconductor lasers.

Each of the semiconductor lasers is maintained at a high temperature and is energized (the second energizing step of applying an electric current again: step S26). More specifically, an electric current is again applied to the semiconductor lasers that do not satisfy the predetermined selecting requirements. The second energizing step is carried out under such conditions that the threshold current Ith having degraded in the first energizing step recovers. In other words, the energization through the first and second energizing steps recovers the threshold current Ith (the characteristics) of the semiconductor laser that deteriorated once. This energization is equivalent to the energization performed for the energizing time T2-T1 shown in FIG. 3. For example, the energization is performed at an operating temperature of 80° C. for 50 hours, with an electric current of 120 mA being applied to each semiconductor laser. The same test as in step S14 of the first embodiment is then conducted (step S28). The semiconductor lasers that have passed the test are determined to be normal products (step S32). The semiconductor lasers that have failed the test are determined to be defective products (step S30).

In the second embodiment, the second energizing step (step S26) is carried out for the semiconductor lasers that have deteriorated in the first energizing step (step S22). In the first embodiment, energization over a long period of time equivalent to the time T2 of FIG. 3 is performed for all the semiconductor lasers. As a result, the production costs become unreasonably large where most of the semiconductor lasers produced in step S10 do not deteriorate in the energizing step, like the semiconductor laser A of FIG. 3. In the second embodiment, on the other hand, the semiconductor laser A of FIG. 3 is determined to be a normal product (step S32) through the test (step S24) conducted after the first energizing step (S22). The second energizing step (step S26) is carried out for the semiconductor lasers B and C of FIG. 3. In this manner, the number of semiconductor lasers for which long-time energization is performed can be reduced. Thus, the production costs can be lowered.

The first energizing step (step S12) of the first embodiment, and the first energizing step (step S22) and the second energizing step (step S26) of the second embodiment may be carried out at an operating temperature of 25 to 100° C. for one to 50 hours, with the value of the applied current being ±50% of the threshold current Ith, for example. However, those values may be changed so that each semiconductor laser can recover from deterioration caused by the application of an electric current. For example, energization is performed at a temperature higher than room temperature, so that the threshold current of the semiconductor laser C can recover in a short time.

In the first and second embodiments, the compound semiconductor layer has the side faces of each ridge portion 36 containing AlGaInP. However, a defective layer having a Ga defect like a defective layer 52 shown in FIG. 5 is formed, as long as the compound semiconductor layer contains Ga. As a result, a current that flows through the defective layer is generated. The present invention is applied to such a semiconductor laser manufacturing method, so that the production costs can be lowered as in the first and second embodiments. The compound semiconductor layer containing Ga may be a compound semiconductor layer that contains at least one of GaAs, AlGaAs, GaP, GaInP, and AlGaInP. Such compound semiconductor layers containing Ga are mostly used for short-wavelength semiconductor lasers that serve as the light sources for optical discs such as CDs and DVDs. Furthermore, there is a strong demand for reductions in production costs at which semiconductor lasers to be used as the light sources for optical discs are mass-produced, and the manufacturing methods in accordance with the present invention are particularly effective.

In the first and second embodiments, the energizing step (step S12 or S22) is carried out, with the silicon nitride film 26 being formed on the surface of each ridge portion 36. However, it is possible to form a film other than a silicon nitride film on the surface of each ridge portion 36. As long as a film that diffuses Ga in the compound semiconductor layer containing Ga is employed, the effect of the present invention can be achieved. Accordingly, at least one of a silicon nitride film, a silicon oxide film, and a silicon oxynitride film may be formed on the surface of each ridge portion 36.

Finally, various aspects of the present invention are summarized in the following.

There is provided a method of manufacturing a semiconductor laser that has a ridge portion formed with a compound semiconductor layer containing Ga, the method including: applying an electric current to the semiconductor laser until characteristics of the semiconductor laser that deteriorate due to the application of the electric current recover from the deterioration.

There is provided a method of manufacturing a semiconductor laser that has a ridge portion formed with a compound semiconductor layer containing Ga, the method including: applying an electric current to the semiconductor laser; distinguishing the semiconductor laser that does not satisfy predetermined selecting requirements from other semiconductor lasers after the step of applying an electric current; and applying an electric current again to the semiconductor laser that does not satisfy the predetermined selecting requirements, energization through the step of applying an electric current and the step of applying an electric current again being performed to recover characteristics of the semiconductor laser from deterioration.

In the above-described method, applying an electric current may be carried out at a higher temperature than room temperature.

In the above-described method, at least one of applying an electric current and applying an electric current again may be carried out at a higher temperature than room temperature. The period of time required for carrying out the step of applying an electric current can be shortened, and the production costs can be lowered.

In the above-described method, the compound semiconductor layer containing Ga may be a compound semiconductor layer that contains at least one of GaAs, AlGaAs, GaP, GaInP, and AlGaInP.

In the above-described method, the semiconductor laser may be to be used as a light source for optical discs.

In the above-described method, a characteristic of the semiconductor laser may be a lasing threshold current of the semiconductor laser.

In the above-described method, applying an electric current may be carried out, with at least one of a silicon nitride film, a silicon oxide film, and a silicon oxynitride film being formed on a surface of the compound semiconductor layer of the ridge portion.

As described above, the present invention can provide a semiconductor laser manufacturing method that can reduce the number of semiconductor lasers that deteriorate due to the application of an electric current and lower the production costs.

Although a few specific exemplary embodiments employed in the present invention have been shown and described, it would be appreciated by those skilled in the art that changes may be made in these exemplary embodiments without departing from the principles and spirit of the invention, the scope of which is defined in the claims and their equivalents.

The present invention is based on Japanese Patent Application No. 2006-071737 filed on Mar. 15, 2006, the entire disclosure of which is hereby incorporated by reference.

What is claimed is:

1. A method of manufacturing a semiconductor laser that has a ridge portion formed with a compound semiconductor layer containing Ga, the method comprising:
applying an electric current to the semiconductor laser until characteristics of the semiconductor laser that deteriorate due to the application of the electric current recover from the deterioration.

2. A method of manufacturing a semiconductor laser that has a ridge portion formed with a compound semiconductor layer containing Ga, the method comprising:
applying an electric current to the semiconductor laser;
distinguishing the semiconductor laser that does not satisfy predetermined selecting requirements from other semiconductor lasers after the step of applying an electric current; and
applying an electric current again to the semiconductor laser that does not satisfy the predetermined selecting requirements,
energization through the step of applying an electric current and the step of applying an electric current again being performed to recover characteristics of the semiconductor laser from deterioration.

3. The method as claimed in claim 1, wherein applying an electric current is carried out at a higher temperature than room temperature.

4. The method as claimed in claim 2, wherein at least one of applying an electric current and applying an electric current again is carried out at a higher temperature than room temperature.

5. The method as claimed in claim 1, wherein the compound semiconductor layer containing Ga is a compound semiconductor layer that contains at least one of GaAs, AlGaAs, GaP, GaInP, and AlGaInP.

6. The method as claimed in claim 1, wherein the semiconductor laser is to be used as a light source for optical discs.

7. The method as claimed in claim 1, wherein a characteristic of the semiconductor laser is a lasing threshold current of the semiconductor laser.

8. The method as claimed in claim 1, wherein applying an electric current is carried out, with at least one of a silicon nitride film, a silicon oxide film, and a silicon oxynitride film being formed on a surface of the compound semiconductor layer of the ridge portion.

9. The method as claimed in claim 2, wherein the compound semiconductor layer containing Ga is a compound semiconductor layer that contains at least one of GaAs, AlGaAs, GaP, GaInP, and AlGaInP.

10. The method as claimed in claim 2, wherein the semiconductor laser is to be used as a light source for optical discs.

11. The method as claimed in claim 2, wherein a characteristic of the semiconductor laser is a lasing threshold current of the semiconductor laser.

12. The method as claimed in claim 2, wherein applying an electric current is carried out, with at least one of a silicon nitride film, a silicon oxide film, and a silicon oxynitride film being formed on a surface of the compound semiconductor layer of the ridge portion.
